(19) United States
(12) Patent Application Publication
(10) Pub. No.: US 2023/0197754 A1
(43) Pub. Date: Jun. 22, 2023

(54) IMAGE SENSOR

(71) Applicant: SAMSUNG ELECTRONICS CO., LTD., SUWON-SI (KR)

(72) Inventor: JONGMIM JEON, SUWON-SI (KR)

(21) Appl. No.: 18/079,165

(22) Filed: Dec. 12, 2022

(30) Foreign Application Priority Data
Dec. 22, 2021 (KR) 10-2021-0185406

(51) Int. Cl. H01L 27/146

(52) U.S. Cl. CPC H01L 27/1463; H01L 27/14621; H01L 27/14623; H01L 27/14627; H01L 27/14645

(57) ABSTRACT

An image sensor includes; a substrate including a photoelectric conversion region, a first isolation region extending vertically into the substrate from a first surface of the substrate, a second isolation region extending vertically into the substrate from a second surface of the substrate and corresponding to the first isolation region, a photoelectric conversion device disposed at a central portion of the photoelectric conversion region of the substrate, and a contact region extending vertically from the second surface of the substrate to electrically connect the first isolation region at a peripheral portion of the photoelectric conversion region, wherein the second isolation region includes; a trench, an insulating liner conformally formed on an inner wall of the trench, a trap conductive film conformally formed on an inner wall of the insulating liner, and an insulating filling layer filling a residual portion of the trench and including an air gap.

### CROSS-REFERENCE TO RELATED APPLICATION

This application claims priority under 35 U.S.C. § 119 to Korean Patent Application No. 10-2021-0185406 filed on Dec. 22, 2021 in the Korean Intellectual Property Office, the subject matter of which is hereby incorporated by reference in its entirety.

### BACKGROUND

The inventive concept relates generally to image sensors and, more particularly, to image sensors capable of providing a clear image signal.

Image sensors convert an optical image into a corresponding electrical signal. Image sensors may be generally categorized as charge-coupled device (CCD) image sensors and Complementary Metal Oxide Semiconductor (CMOS) image sensors (or CIS). Image sensors usually include pixels arranged in a matrix of rows and columns, wherein each pixel outputs an image signal in response incident light. In this regard, each pixel accumulates photo-charge corresponding to an amount of incident light through a photoelectric conversion device, and then outputs a pixel signal based on the accumulated photo-charge. More recently, as the integration density of image sensors has increased, the size of respective pixels has decreased along with the other components and component features associated with pixels..

### SUMMARY

Embodiments of the inventive concept provide image sensors that provide a clear image signal by arranging a trap conductive film capable of trapping surplus electrons in a backside deep trench isolation.

An image sensor according to embodiments of the inventive concept may include; a substrate having a first surface and an opposing second surface and including a photoelectric conversion region, a first isolation region extending vertically into the substrate from the first surface of the substrate, a second isolation region extending vertically into the substrate from the second surface of the substrate and corresponding to the first isolation region, a photoelectric conversion device disposed at a central portion of the photoelectric conversion region of the substrate, and a contact region extending vertically from the second surface of the substrate to electrically connect the first isolation region at a peripheral portion of the photoelectric conversion region, wherein the second isolation region includes; a trench, an insulating liner conformally formed on an inner wall of the trench, a trap conductive film conformally formed on an inner wall of the insulating liner, and an insulating filling layer filling a residual portion of the trench and including an air gap.

An image sensor according to embodiments of the inventive concept may include; a substrate having a first surface and an opposing second surface, and including a photoelectric conversion region, a first isolation region vertically extending into the substrate from the first surface of the substrate, a second isolation region vertically extending into the substrate from the second surface of the substrate and corresponding to the first isolation region, a photoelectric conversion device disposed at a central portion of the photoelectric conversion region, and a contact region vertically extending into the substrate from the second surface of the substrate to electrically connect the first isolation region at a peripheral portion of the photoelectric conversion region, wherein the second isolation region includes; a trench, an insulating liner conformally formed on an inner wall of the trench, a trap conductive film conformally formed on an inner wall of the insulating liner and electrically connected to the contact region, and an insulating filling layer entirely filling a residual portion of the trench.

An image sensor according to embodiments of the inventive concept may include; a substrate having a front surface and an opposing rear surface, and including a photoelectric conversion region, a first isolation region arranged in a lattice pattern and vertically extending into the substrate from the front surface of the substrate, wherein the first isolation region includes; a first trench, an insulating barrier formed on an inner wall of the first trench, and a conductive filling film filling a residual portion of the first trench, a second isolation region arranged in a lattice pattern and vertically extending into the substrate from the rear surface to contact the first isolation region, wherein the second isolation region includes; a second trench, an insulating liner conformally formed on an inner wall of the second trench, a trap conductive film conformally formed on an inner wall of the insulating liner, and an insulating filling layer filling a residual portion of the second trench and including an air gap, and a contact region vertically extending from the rear surface to electrically connect the conductive filling film of the first isolation region and the trap conductive layer of the second isolation region, wherein the photoelectric conversion region includes; a photoelectric conversion device disposed in an inner portion of the substrate, a color filter disposed on the rear surface of the substrate, and a microlens disposed on the color filter.

### BRIEF DESCRIPTION OF THE DRAWINGS

Advantages, benefits, and features, as well as the making and use of the inventive concept, may be more clearly understood upon consideration of the following detailed description together with the accompanying drawings, in which:

FIG. 1 is a circuit diagram illustrating a pixel array of an image sensor according to embodiments of the inventive concept;

FIG. 2 is a plan (or top-down) view illustrating a pixel array of an image sensor according to embodiments of the inventive concept;

FIG. 3 is a plan view illustrating an image sensor according to embodiments of the inventive concept;

FIG. 4 is a cross-sectional view illustrating an image sensor according to embodiments of the inventive concept;

FIG. 5 is an enlarged cross-sectional view further illustrating section ‘V’ of FIG. 4;

FIG. 6 is a cross-sectional view illustrating an image sensor according to embodiments of the inventive concept;

FIG. 7 is an enlarged cross-sectional view further illustrating section ‘VII’ of FIG. 6;

FIG. 8 is a flowchart illustrating a method of manufacture for an image sensor according to embodiments of the inventive concept;

FIGS. 9, 10, 11, 12, 13, 14, ,15, 16, 17 and 18 (hereafter collectively, “FIGS. 9 to 18” are related cross-sectional views illustrating a method of manufacture for an image sensor according to embodiments of the inventive concept;

FIG. 19 is a block diagram illustrating an electronic device that may include a multi-camera module incorporating an image sensor according to embodiments of he inventive concept;

FIG. 20 is a block diagram further illustrating the camera module of FIG. 19; and

FIG. 21 is a block diagram illustrating an image sensor according to embodiments of the inventive concept.

### DETAILED DESCRIPTION

Throughout the written description and drawings. like reference numbers and labels are used to denote like or similar elements and/or features.

Throughout the written description certain geometric terms may be used to highlight relative relationships between elements, components and/or features with respect to certain embodiments of the inventive concept. Those skilled in the art will recognize that such geometric terms are relative in nature, arbitrary in descriptive relationship(s) and/or directed to aspect(s) of the illustrated embodiments. Geometric terms may include, for example: height/width; vertical/horizontal; top/bottom; higher/lower; closer/farther; thicker/thinner; proximate/distant; above/below; under/over; upper/lower; center/side; surrounding; overlay/underlay; etc.

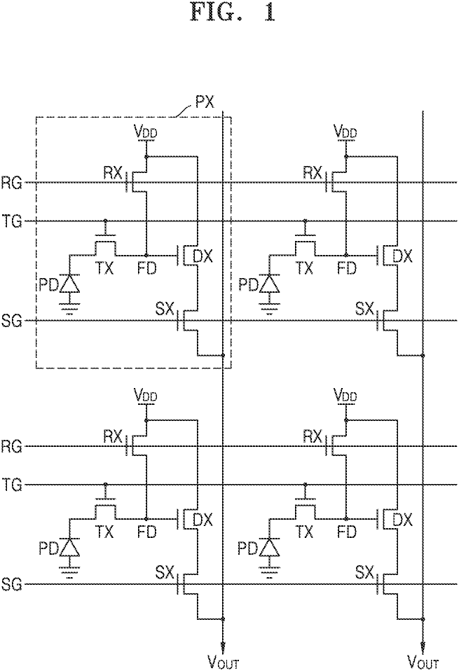

Figure FIG. 1 is a circuit diagram illustrating, in part, a pixel array of an image sensor according to embodiments of the inventive concept.

Referring to FIG. 1, a unit pixel PX includes a transmission transistor TX and logic transistors RX, SX, and DX.

In some embodiments, unit pixels PX may be arranged in a matrix of rows and columns. Here, the logic transistors may include a reset transistor RX, a selection transistor SX, and a drive transistor DX (or a source follower transistor). The reset transistor RX may include a reset gate RG, and the selection transistor SX may include a selection gate SG. In addition, the transmission transistor TX may include a transmission gate TG.

The unit pixel PX may include a photoelectric conversion device PD and a floating diffusion region FD. The photoelectric conversion device PD may generate and accumulate photo-charge in proportion to an amount of incident light (e.g., externally provided electromagnetic energy in a defined bandwidth). In this regard, the photoelectric conversion device PD may be, for example, a photo diode, a photo transistor, a photo gate, and/or a pinned photo diode (PPD).

The transmission gate TG may transmit photo-charge generated by the photoelectric conversion device PD to the floating diffusion region FD. Thus, the floating diffusion region FD may receive the photo-charge generated by the photoelectric conversion device PD and store the photo-charge accumulated therein. The drive transistor DX may be controlled according to the amount of photo-charge accumulated in the floating diffusion region FD.

The reset transistor RX may be used to periodically reset the photo-charge accumulated in the floating diffusion region FD. A drain electrode of the reset transistor RX may be connected to the floating diffusion region FD, and a source electrode of the reset transistor RX may be connected to a power supply voltage (e.g., V_{DD}).

When the reset transistor RX is turned ON, the power supply voltage V_{DD} connected to the source electrode of the reset transistor RX may be transferred to the floating diffusion region FD. When the reset transistor RX is turned ON, the photo-charge accumulated in the floating diffusion region FD are discharged, thereby resetting the floating diffusion region FD.

The drive transistor DX may be connected to a current source (not shown in FIG. 1) external to the unit pixel PX to function as a source follower buffer amplifier, amplify a potential change in the floating diffusion region FD, and output same to an output line V_{OUT·}

The selection transistor SX may be used to select unit pixels PX (e.g.,) in row units. Thus, when the selection transistor SX is turned ON, the power supply voltage V_{DD} may be transferred to the source electrode of the drive transistor DX.

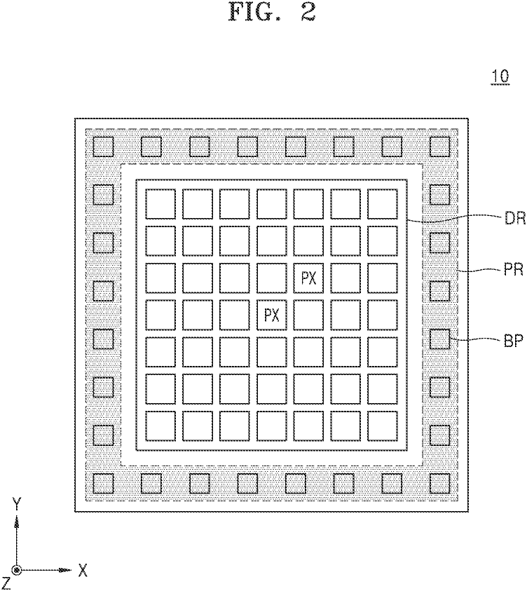

FIG. 2 is a plan view illustrating a pixel array of an image sensor according to embodiments of the inventive concept.

Referring to FIG. 2, the image sensor 10 may include a device region DR in which a unit pixels PX are arranged, and a pad region PR substantially surrounding the device region DR and including a peripheral circuit.

In the image sensor 10, unit pixels PX may be understood as being arranged in the device region DR as a matrix defined by a first horizontal direction (e.g., an X direction) and a second horizontal direction (e.g., a Y direction) substantially perpendicular to the first horizontal direction. Here, the respective unit pixels PX may include the logic transistors as described above.

Referring to FIGS. 1 and 2, the logic transistors may include the reset transistor RX, the selection transistor SX, and the drive transistor DX. The reset transistor RX may include the reset gate RG, the selection transistor SX may include the selection gate SG, and the transmission transistor TX may include the transmission gate TG.

In addition, each of the unit pixels PX may include the photoelectric conversion device PD and the floating diffusion region FD.

Although the pad region PR is shown in FIG. 2 as surrounding the device region DR, this is just one possible example, and the inventive concept is not limited thereto.

The pad region PR may include buried pads BP electrically connected to the unit pixels PX and the peripheral circuit, and the buried pads BP may function as a connection terminal providing external power and/or various signals to the unit pixels PX and/or the peripheral circuit.

In some embodiments, the image sensor 10 of FIG. 2 may include one or more features of image sensors 100 and 200 described hereafter. That is, the image sensor 10 may be used to provide a clear image signal by arranging a trap conductive film capable of trapping surplus electrons in a backside deep trench isolation.

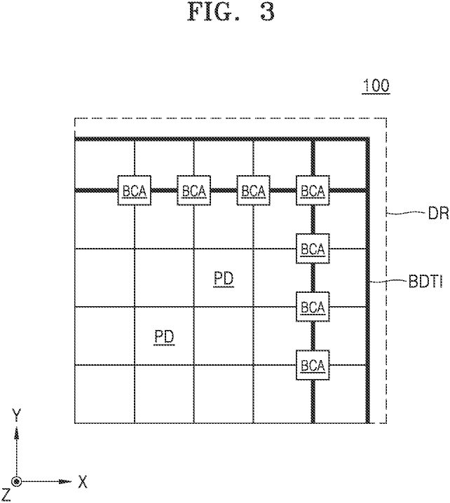

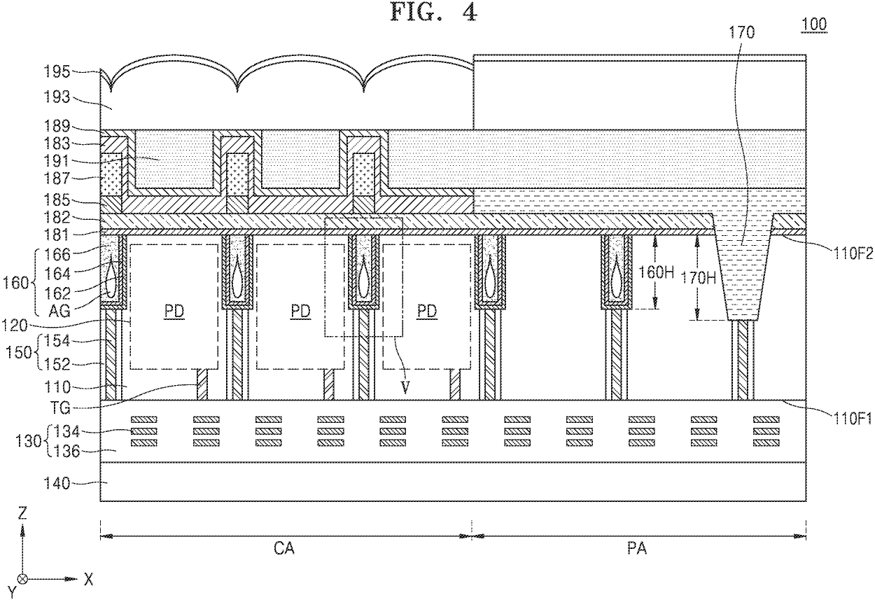

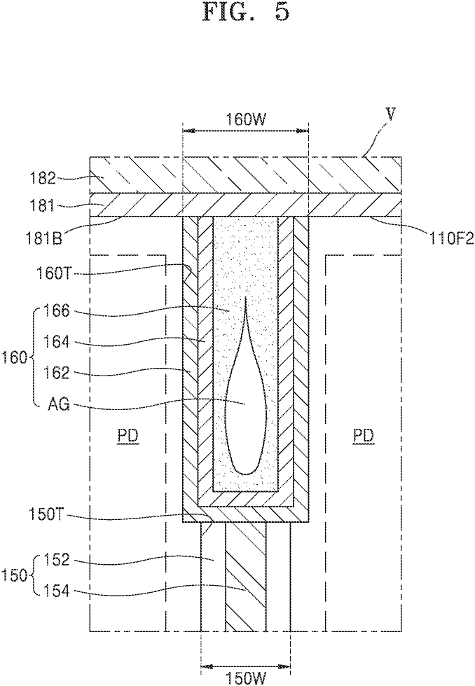

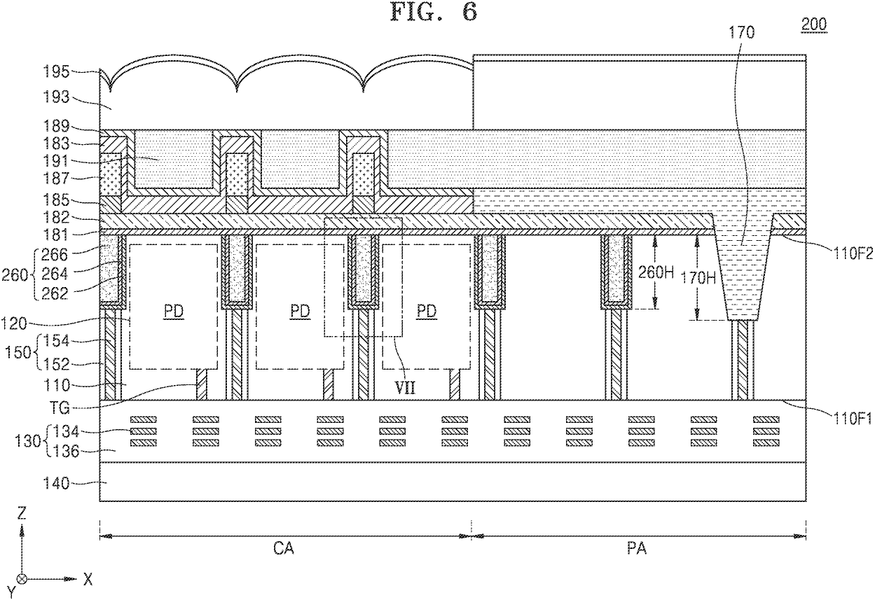

FIG. 3 is a plan view illustrating a portion (e.g., an upper right corner portion) of an image sensor 100 according to embodiments of the inventive concept; FIG. 4 is a cross-sectional view further illustrating the image sensor 100, and FIG. 5 is an enlarged cross-sectional view further illustrating section ‘V’ of FIG. 4.

Referring to FIGS. 1, 3, 4 and 5, the image sensor 100 may include a substrate 110, a photoelectric conversion region 120, a frontside structure 130, a support substrate 140, a first isolation region 150, a second isolation region 160, a contact region 170, first to third anti-reflection layers 181, 182, and 183, a color filter 191, a microlens 193, and a capping layer 195.

The substrate 110 may include a first surface 110F1 and an opposing second surface 110F2. In some embodiments, the substrate 110 may include a Group IV semiconductor material, a Group III-V semiconductor material, or a Group II-VI semiconductor material. The Group IV semiconductor material may include, for example, silicon (Si), germanium (Ge), or silicon germanium (SiGe). The Group III-V semiconductor material may include, for example, gallium arsenic (GaAs), indium phosphorus (InP), gallium phosphorus (GaP), indium arsenic (InAs), indium antimony (InSb), or indium gallium arsenic (InGaAs). The group II-VI semiconductor material may include, for example, zinc telluride (ZnTe) or cadmium sulfide (CdS).

The substrate 110 may include a semiconductor substrate. For example, the substrate 110 may include a P-type silicon substrate. In some embodiments, the substrate 110 may include a P-type bulk substrate and a P-type or N-type epitaxial layer grown thereon. In other embodiments, the substrate 110 may include an N-type bulk substrate and a P-type or N-type epitaxial layer grown thereon. Alternately or additionally, the substrate 110 may include an organic plastic substrate.

The photoelectric conversion region 120 may be arranged in the substrate 110. The photoelectric conversion region 120 may convert an optical signal into an electrical signal. The photoelectric conversion region 120 may include a photoelectric conversion device PD formed within the substrate 110. The photoelectric conversion region 120 may be an impurity region doped with impurities of a conductivity type opposite to the conductivity type of the substrate 110. The photoelectric conversion region 120 may be generally divided into a central area CA in which the photoelectric conversion device PD is arranged and a peripheral area PA in which the photoelectric conversion device PD is not arranged. The photoelectric conversion device PD may generate and accumulate photo-charge in proportion to an amount of incident light, and may include a photo diode, a photo transistor, a photo gate, and/or a pinned photo diode (PPD).

The transmission gate TG may be arranged in the substrate 110. The transmission gate TG may extend from the first surface 110F1 of the substrate 110 to within the substrate 110. The transmission gate TG may be a part of the transmission transistor TX. Here, the first surface 110F1 of the substrate 110 may include: (1) the transmission transistor TX which is configured to transmit electrical charge generated by the photoelectric conversion region 120 to a floating diffusion region FD; (2) the reset transistor RX which is configured to periodically reset the electrical charge stored in the floating diffusion region FD; (3) the drive transistor DX serving as a source follower buffer amplifier and configured to buffer a signal according to the electrical charge accumulated in the floating diffusion region FD; and (4) the selection transistor SX which is configured to select among the unit pixels PX.

The photoelectric conversion region 120, the transmission gate TG, the transistors, and the floating diffusion region may constitute the unit pixel PX. In some embodiments, the unit pixels PX may include active pixels including a photoelectric conversion device PD and dummy pixels that do not include a photoelectric conversion device PD.

In some embodiments, the pixel array including the unit pixels PX of FIG. 1 may be formed in such a manner that one of a horizontal dimension and a vertical dimension of the pixel array is longer than the other. For example, when the horizontal dimension of the pixel array is longer than the vertical dimension, a number of horizontally arranged rear contact arrays BCA may be greater than a number of vertically arranged rear contact arrays BCA, or an interval between horizontally arranged rear contact arrays BCA may be greater than an interval between vertically arranged rear contact arrays BCA.

The frontside structure 130 may be disposed on the first surface 110F1 of the substrate 110. The frontside structure 130 may include a wiring layer 134 and an insulating layer 136. The insulating layer 136 may electrically isolate the wiring layer 134 on the first surface 110F1 of the substrate 110.

The wiring layer 134 may be electrically connected to the transistors on the first surface 110F1 of the substrate 110. The wiring layer 134 may include, for example, tungsten, aluminum, copper, tungsten silicide, titanium silicide, tungsten nitride, titanium nitride, and/or doped polysilicon. The insulating layer 136 may include an insulating material, such as for example, silicon oxide, silicon nitride, silicon oxynitride, and a low-k dielectric material. Optionally, the support substrate 140 may be disposed on the frontside structure 130. An adhesive member (not shown) may be disposed between the support substrate 140 and the frontside structure 130.

The first isolation region 150 extends in a vertical direction (or a Z direction) substantially perpendicular to the first surface 110F1 of the substrate 110 (assumed for purposes of illustration to be oriented in a horizontal plane defined by the first horizontal direction and the second horizontal direction). Here, the vertically-extending, first isolation region 150 may physically and electrically isolate one photoelectric conversion device PD from an adjacent photoelectric conversion device PD. In this regard, the first isolation region 150 may be arranged in a lattice pattern (e.g., a mesh pattern or a grid pattern). Further in this regard, the first isolation region 150 may extend between the photoelectric conversion regions 120.

The first isolation region 150 may include an insulating barrier 152 and a conductive filling film 154 substantially surrounded by the insulating barrier 152 in a first trench 150T. Each of the insulating barrier 152 and the conductive filling film 154 may be formed within the substrate 110 in the vertical direction perpendicular to the first surface 110F1 of the substrate 110. The insulating barrier 152 may be conformally arranged between the substrate 110 and the conductive filling film 154 to electrically isolate the conductive filling film 154 from the substrate 110.

The insulating barrier 152 may include a metal oxide, such as for example, hafnium oxide, aluminum oxide, and tantalum oxide. Thus, the insulating barrier 152 may function as a negative fixed charge layer. In other embodiments, the insulating barrier 152 may include an insulating material, such as for example, silicon oxide, silicon nitride, and/or silicon oxynitride. In some embodiments, the conductive filling film 154 may include a conductive material, such as for example, doped polysilicon or metal.

The second isolation region 160 extends vertically towards the second surface 110F2 of the substrate 110 and may physically and electrically isolate one photoelectric conversion device PD from an adjacent photoelectric conversion device PD. Here, the second isolation region 160 may be arranged in a lattice pattern (e.g., a mesh pattern or a grid pattern). That is, the second isolation region 160 may extend between the photoelectric conversion regions 120.

The second isolation region 160 may be formed in a trench of a deep trench isolation (DTI) pattern. For example, the second isolation region 160 may include an insulating liner 162 conformally formed on an inner wall of a second trench 160T, a trap conductive film 164 conformally formed on an inner wall of the insulating liner 162, and an insulating filling layer 166 filling a residual portion of the second trench 160T (e.g., a portion of the trench 160T not filled by the insulating layer 162, and the trap conductive film 164) and also including an air gap AG.

The insulating liner 162 may include silicon oxide or a high-k dielectric material layer having a dielectric constant higher than silicon oxide. The trap conductive film 164 may include at least one of, for example, doped polysilicon, titanium (Ti), tungsten (W), aluminum (Al), and indium tin oxide (ITO). The trap conductive film 164 including at least one electrically conductive material may be arranged to be electrically connected to the contact region 170, as will be described hereafter in some additional detail. The insulating filling layer 166 may include an oxide layer formed by a process with relatively poor step coverage. For example, the insulating filling layer 166 may include at least one of plasma enhanced oxide (PE-OX), tetraethyl orthosilicate (TEOS), and plasma enhanced-TEOS (PE-TEOS), but is not limited thereto. In some embodiments, the insulating filling layer 166 may include silicon oxide, silicon nitride, and/or silicon oxynitride. The insulating filling layer 166 may include a low-k dielectric material layer having a dielectric constant lower than that of silicon oxide. That is, the first dielectric constant of the insulating liner 162 in the second isolation region 160 may be greater than the second dielectric constant of the insulating filling layer 166.

The insulating filling layer 166 may be a material layer formed by a process in which step coverage is relatively poor. In this regard, the term “air gap AG” may refer to a portion in which the insulating filling layer 166 does not fill the space of the second trench 160T. That is, because the second trench 160T has a large aspect ratio, a process with good step coverage should be used to the whole second trench 160T. However, in order to intentionally form the air gap AG, the image sensor 100 according to embodiments of the inventive concept may use a process in which step coverage is relatively poor during the formation of the insulating filling layer 166.

Thus, the air gap AG may include air which has a low dielectric constant. Accordingly, because the air gap AG has a dielectric constant of about 1, as formed within the second isolation region 160, a parasitic capacitance arising between the second isolation regions 160 may be reduced.

The first isolation region 150 and the second isolation region 160 may be in direct contact with each other to pass through the substrate 110. Specifically, the insulating liner 162 of the second isolation region 160 may be in direct contact with the insulating barrier 152 and the conductive filling film 154 of the first isolation region 150. That is, the first isolation region 150 and the second isolation region 160 are in direct contact with each other, but may not be electrically connected. In addition, a first width 150W measured in the first horizontal direction of the first isolation region 150 may be less than a second width 160W measured in the first horizontal direction of the second isolation region 160, but is not limited thereto.

As shown in cross-section, a length 160H of the second isolation region 160 in the vertical direction may be less than a length 170H of the contact region 170 in the vertical direction.

The contact region 170 may be formed to be electrically connected to the first isolation region 150 in the vertical direction. The contact region 170 may include a metal material, such as tungsten. The contact region 170 may be formed to be in contact with a portion of the first isolation region 150 and the trap conductive film 164 of the second isolation region 160. In addition, the contact region 170 may provide a path for supplying a voltage to the first isolation region 150 by the power supply voltage V_{DD}. (See, e.g., FIG. 1). In some embodiments, the lowermost surface of the contact region 170 may be formed to contact the conductive filling film 154 of the first isolation region 150. In the contact region 170, a number of contacts may constitute a contact array, and the contact array may be formed in a dummy pixel or area not including a photoelectric conversion device PD.

The first anti-reflection layer 181 may be disposed on the second surface 110F2 of the substrate 110. That is, the first anti-reflection layer 181 may be disposed on all the photoelectric conversion devices PD and the second isolation region 160. That is, a lowermost surface 181B of the first anti-reflection layer 181 may be in direct contact with the uppermost surface of the insulating liner 162, the uppermost surface of the trap conductive film 164, and the uppermost surface of the insulating filling layer 166 of the second isolation region 160. However, the lowermost surface 181B of the first anti-reflection layer 181 may not contact with the air gap AG of the second isolation region 160. In some embodiments, the first anti-reflection layer 181 may include aluminum oxide, but is not limited thereto.

The second anti-reflection layer 182 may be disposed on the first anti-reflection layer 181. That is, the second anti-reflection layer 182 may be disposed on all the photoelectric conversion devices PD and the second isolation region 160. In some embodiments, the second anti-reflection layer 182 may include hafnium oxide, but is not limited thereto.

A barrier metal layer 185 and a fence 187 may be disposed on the second anti-reflection layer 182. In some embodiments, the barrier metal layer 185 may include a barrier metal, such as titanium nitride. The fence 187 may overlap the first isolation area 150 and the second isolation area 160 in a plan view. That is, the fence 187 may extend along a space between the photoelectric conversion devices PD in a plan view. In some embodiments, the fence 187 may include a low refractive index material. So, when the fence 187 includes a low refractive index material, incident light illuminating (or directed towards) the fence 187 may be fully reflected (or redirected) towards the center of the photoelectric conversion device PD. In this manner, the fence 187 may prevent obliquely-incident light from migrating into an adjacent color filter 191 disposed on an adjacent photoelectric conversion device PD, thereby preventing or reducing cross-talk between the unit pixels PX.

The third anti-reflection layer 183 may be disposed on the second anti-reflection layer 182 and the fence 187. That is, the third anti-reflection layer 183 may cover the second anti-reflection layer 182 and the fence 187. Here, the third anti-reflection layer 183 may be disposed on the upper surface of the second anti-reflection layer 182, the side surface of the fence 187, and the upper surface of the fence 187. In some embodiments, the third anti-reflection layer 183 may include silicon oxide, but is not limited thereto.

A passivation layer 189 may be disposed on the third anti-reflection layer 183. The passivation layer 189 may serve to protect the third anti-reflection layer 183, the second anti-reflection layer 182, and the fence 187. In some embodiments, the passivation layer 189 may include aluminum oxide, but is not limited thereto.

Color filters 191 may be respectively disposed on the passivation layer 189 and may be isolated from each other by the fences 187. The color filters 191 may be, for example, a combination of green, blue, and red. Alternately, the color filters 191 may be, for example, a combination of cyan, magenta, and yellow.

The microlens 193 may be disposed on the color filters 191 and the passivation layer 189. The microlens 193 may be arranged to correspond to the photoelectric conversion device PD. The microlens 193 may be formed from one or more transparent materials. For example, the microlens 193 may have a transmittance of about 90% or more with respect to incident light in the visible spectrum. The microlens 193 may be formed of, for example, a styrene-based resin, an acrylic-based resin, a styrene-acrylic copolymer-based resin, a siloxane-based resin, etc. In operative effect, the microlens 193 may respectively focus incident light, such that the focused (or condensed) incident light may illuminate the photoelectric conversion region 120 through the color filter 191. The capping layer 195 may be disposed on the microlens 193.

In order to provide improved isolation among the unit pixels PX, a frontside deep trench isolation (FDTI) and a backside deep trench isolation (BDTI) may be formed. However, when performing the BDTI process, if an etching process is performed on a substrate to form a deep trench, a surface defect occurs in a deep trench of the substrate, and the surface defect of the substrate may form dangling bonds. Due to surplus electrons resulting from dangling bonds, a dark current may be generated within a photodiode. This undesirable dark current reduces the overall reliability of the image sensor. And accordingly, embodiments of the inventive concept address this limitation.

For example, the image sensor 100 of FIGS. 3, 4 and 5 includes the trap conductive film 164 arranged in the second isolation region 160 corresponding to the BDTI to address the phenomenon of dark current being generated as the result of forming the BDTI. In this approach, surplus electrons from the dangling bonds may be trapped by a bias applied to the trap conductive film 164, thereby effectively reducing the level of dark current. And ultimately, the image sensor 100 may provide a clear image signal by arranging the trap conductive film 164 capable of trapping surplus electrons in the second isolation region 160 corresponding to the backside deep trench isolation.

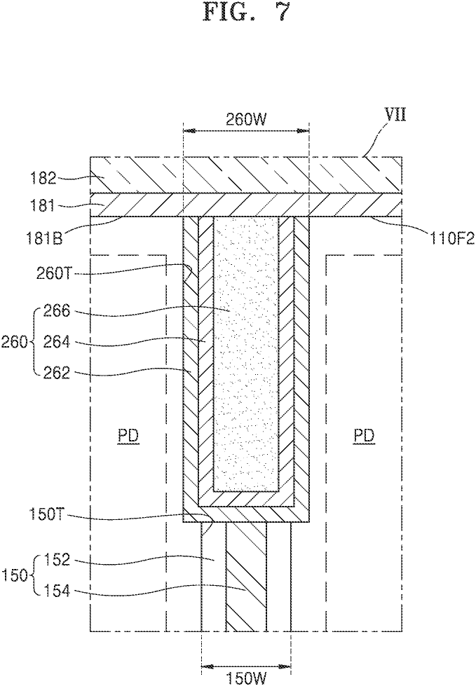

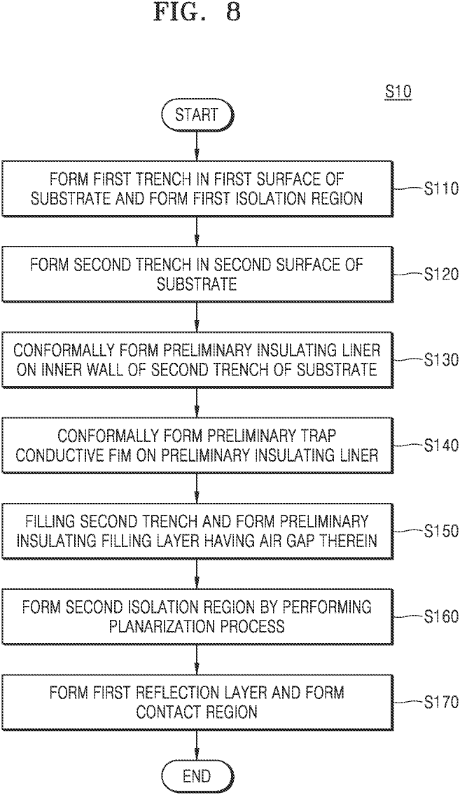

FIG. 6 is a cross-sectional view illustrating another image sensor 200 according to embodiments of the inventive concept, and FIG. 7 is an enlarged cross-sectional view further illustrating section ‘VII’ of FIG. 6. Here, only difference between the image sensor 200 of FIGS. 6 and 7, and the image sensor 100 of FIGS. 3, 4 and 5 will be emphasized.

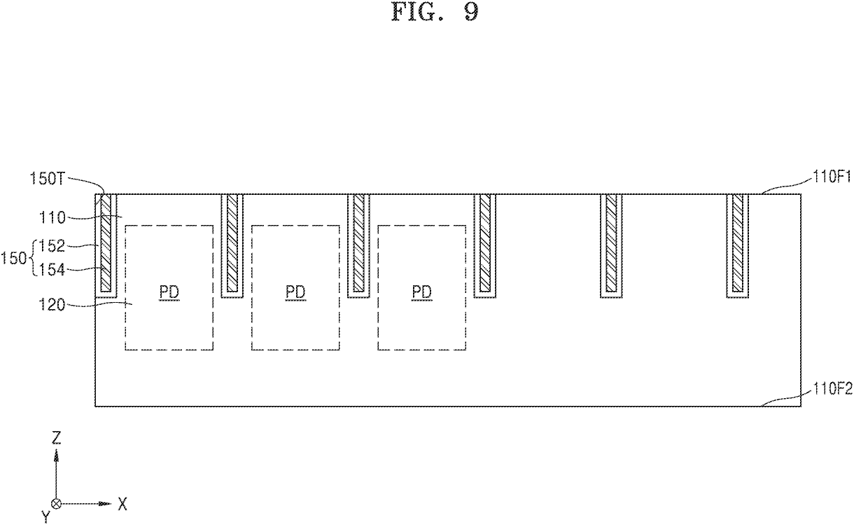

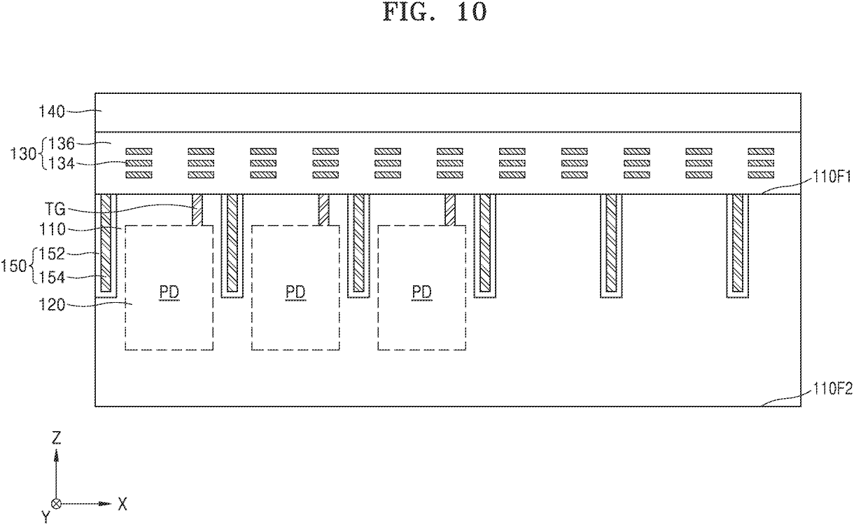

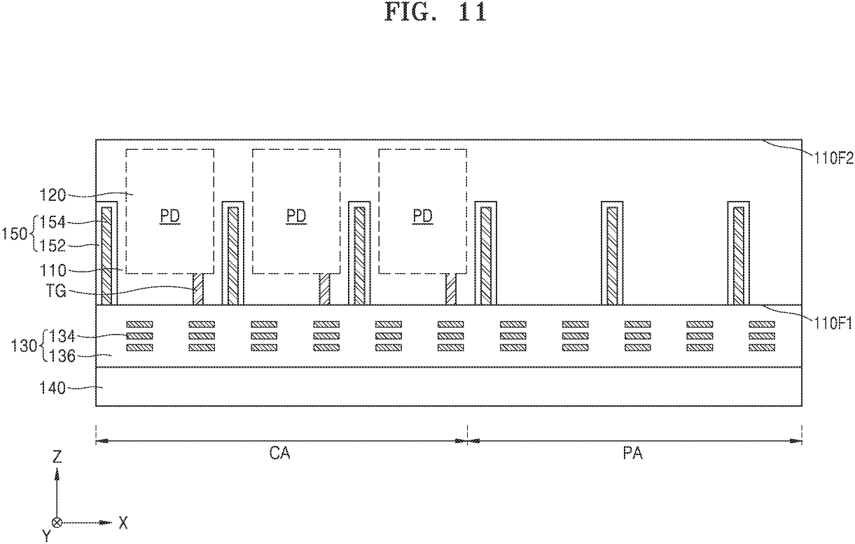

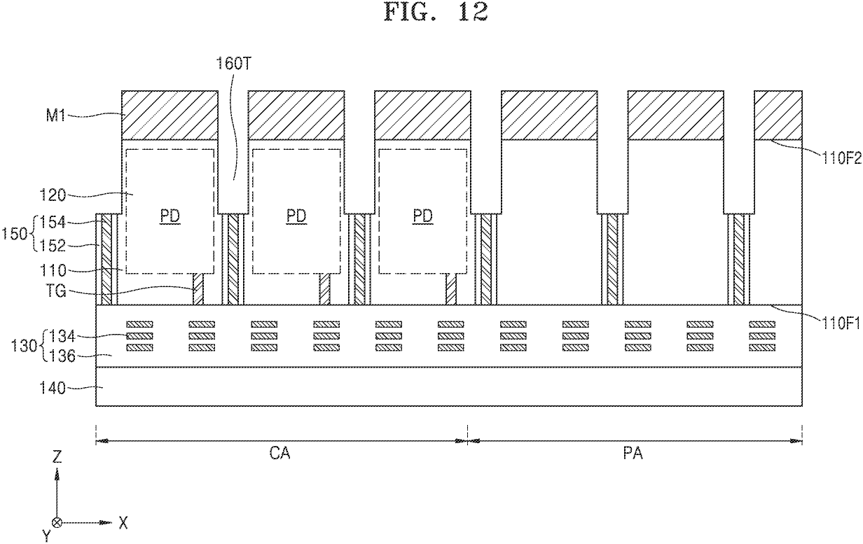

Referring to FIGS. 6 and 7, the image sensor 200 may include a substrate 110, a photoelectric conversion region 120 (see hereafter, e.g., FIG. 9), a frontside structure 130, a support substrate 140, a first isolation region 150, a second isolation region 260, a contact region 170, first to third anti-reflection layers 181, 182, and 183, a color filter 191, a microlens 193, and a capping layer 195.

The image sensor 200 may be arranged the second isolation region 260 including an insulating liner 262 conformally formed on an inner wall of a second trench 260T, a trap conductive film 264 conformally formed on an inner wall of the insulating liner 262, and an insulating filling layer 266 entirely filling a residual portion of the second trench 260T.

The second isolation region 260 vertically extends and may physically and electrically isolate one photoelectric conversion device PD from an adjacent photoelectric conversion device PD. The second isolation region 260 may be arranged in a lattice pattern (e.g., a mesh pattern or a grid pattern). That is, the second isolation region 260 may extend between the photoelectric conversion regions 120.

The insulating liner 262 may include silicon oxide or a high-k dielectric material layer with a dielectric constant higher than silicon oxide. The trap conductive film 264 may include at least one of for example, doped polysilicon, titanium (Ti), tungsten (W), aluminum (Al), and indium tin oxide (ITO). The trap conductive film 264 made include one or more electrically conductive materials and may be arranged to be electrically connected to a contact region 170. The insulating filling layer 266 may include an oxide film formed by a process having relatively good step coverage. For example, the insulating filling layer 266 may include, for example, silicon oxide, silicon nitride, and/or silicon oxynitride formed using an atomic layer deposition (ALD) process or a chemical vapor deposition (CVD) process, but is not limited thereto. In some embodiments, the insulating filling layer 266 may include a low-k dielectric material layer having a dielectric constant lower than that of silicon oxide. That is, the first dielectric constant of the insulating liner 262 in the second isolation region 260 may be greater than the second dielectric constant of the insulating filling layer 266.

The first isolation region 150 and the second isolation region 260 may be in direct contact with each other to pass through the substrate 110. Specifically, the insulating liner 262 of the second isolation region 260 may be in direct contact with the insulating barrier 152 and the conductive filling film 154 of the first isolation region 150. That is, the first isolation region 150 and the second isolation region 260 are in direct contact with each other, but may not be electrically connected. In addition, a first width 150W of the first isolation region 150 may be less than a second width 260W of the second isolation region 260, but is not limited thereto.

When viewed in cross-section, a length 260H of the second isolation region 260 in the vertical direction may be less than a length 170H of the contact region 170 in the vertical direction.

The first anti-reflection layer 181 may be disposed on the second surface 110F2 of the substrate 110. That is, the first anti-reflection layer 181 may be disposed on all the photoelectric conversion devices PD and the second isolation region 260. Specifically, a lowermost surface 181B of the first anti-reflection layer 181 may be in direct contact with the uppermost surface of the insulating liner 262, the uppermost surface of the trap conductive film 264, and the uppermost surface of the insulating filling layer 266 of the second isolation region 260. In some embodiments, the first anti-reflection layer 181 may include aluminum oxide, but is not limited thereto.

The image sensor 200 may include the trap conductive film 264 arranged in the second isolation region 260 corresponding to the BDTI in order to reduced dark current generated as the result of the BDTI being formed. Accordingly, surplus electrons from the dangling bond are trapped by a bias applied to the trap conductive film 264, thereby effectively reducing the dark current. And ultimately, the image sensor 200 of FIG. 6 may provide a clear image signal by arranging the trap conductive film 264 capable of trapping surplus electrons in the second isolation region 260 corresponding to the BDTI.

FIG. 8 is a flowchart illustrating a method of manufacture for an image sensor according to embodiments of the inventive concept.

Referring to FIG. 8, a manufacturing method (S10) for an image sensor according to embodiments of the inventive concept may include processes generally summarized by the method steps of S110 to S170 described hereafter. However, the particular order in which these method steps are performed may vary by design, and two of more method steps may be simultaneously performed.

As set forth in FIG. 8, a method of manufacture for an image sensor according to embodiments of the inventive concept may include: forming a first trench in a first surface of a substrate and forming a first isolation region (S110); forming a second trench in a second surface of the substrate (S120); forming a preliminary insulating liner on the second surface and the inner wall of the second trench of the substrate (S130); conformally forming a preliminary trap conductive film on the preliminary insulating liner (S140); filling the second trench and forming a preliminary insulating filling layer having an air gap therein (S150); forming a second isolation region by performing a planarization process (S160); and forming a first anti-reflection layer and forming a contact region (S170).

Technical features associated with each of these method steps will be described in some additional detail with reference to FIGS. 9 to 18.

FIGS. 9 to 18 are related cross-sectional views illustrating a method of manufacture for image sensor, according to an embodiment of the inventive concept.

Referring to FIG. 9, a substrate 110 having a first surface 110F1 and an opposing second surface 110F2 is prepared.

A mask pattern (not shown) may be formed on the first surface 110F1 of the substrate 110, and a part of the substrate 110 may be removed from the first surface 110F1 of the substrate 110 by using the mask pattern as an etching mask to thereby form a first trench 150T.

Next, an insulating barrier 152 and a conductive filling film 154 are sequentially formed in the first trench 150T, and the insulating barrier 152 and the conductive filling film 154 disposed on the first surface 110F1 of the substrate 110 may be removed by a planarization process to form the first isolation region 150 in the first trench 150T.

Next, a photoelectric conversion region 120 including a photoelectric conversion device PD may be formed by an ion implantation process from the first surface 110F1 of the substrate 110. For example, the photoelectric conversion device PD may be formed by doping N-type impurities.

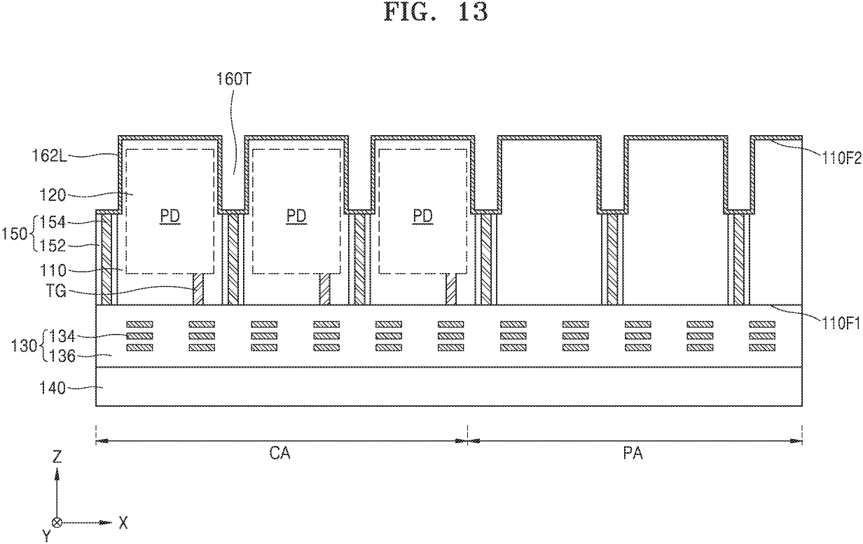

Referring to FIG. 10, a transmission gate TG extending from the first surface 110F1 of the substrate 110 to within the substrate 110 may be formed.

Next, a frontside structure 130 may be formed on the first surface 110F1 of the substrate 110. The operations of forming a conductive layer on the first surface 110F1 of the substrate 110, patterning the conductive layer, and forming an insulating layer to cover the patterned conductive layer may be performed repeatedly, thereby forming a wiring layer 134 and an insulating layer 136.

Optionally, a support substrate 140 may be adhered on the frontside structure 130 using an adhesive member (not shown).

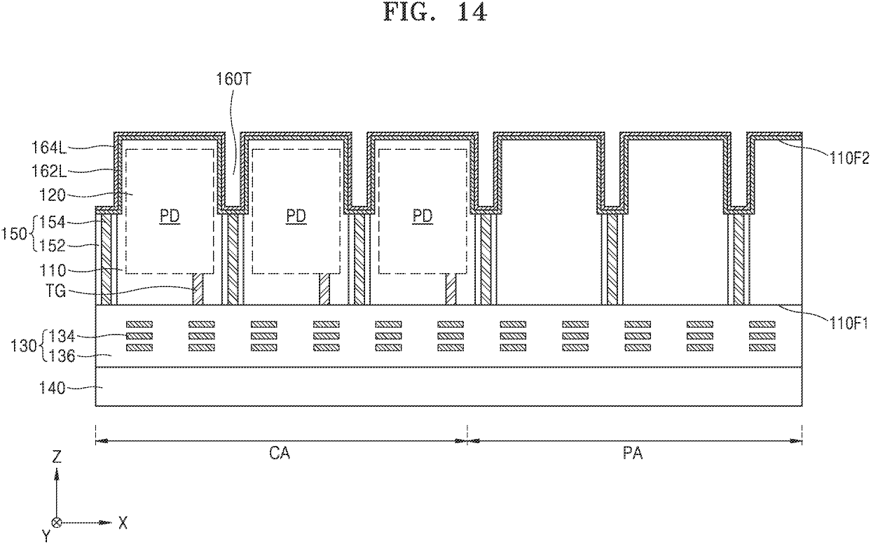

Referring to FIG. 11, the substrate 110 may be turned upside down (or flipped), such that the second surface 110F2 of the substrate 110 faces upward.

Next, a portion of the substrate 110 may be removed from the second surface 110F2 of the substrate 110 by a planarization process, such as a chemical mechanical polishing (CMP) process or an etch-back process. As the removal process is performed, the level of the second surface 110F2 of the substrate 110 may decrease.

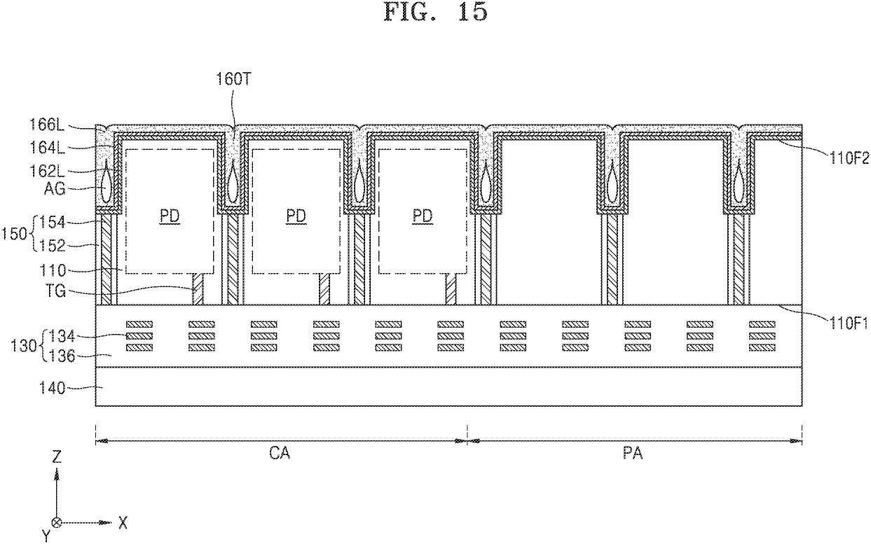

Referring to FIG. 12, a first mask pattern M1 may be formed on the second surface 110F2 of the substrate 110.

The first mask pattern M1 is an etching mask for forming an inner space defining the second isolation region 160 (see e.g., FIG. 16) within the substrate 110, and may be formed by a photolithography process.

Next, by removing a portion of the substrate 110 using the first mask pattern M1 as an etching mask, the second trench 160T may be formed in the third direction (Z direction) perpendicular to the second surface 110F2 of the substrate 110. Next, the first mask pattern M1 may be removed by ashing and strip processes.

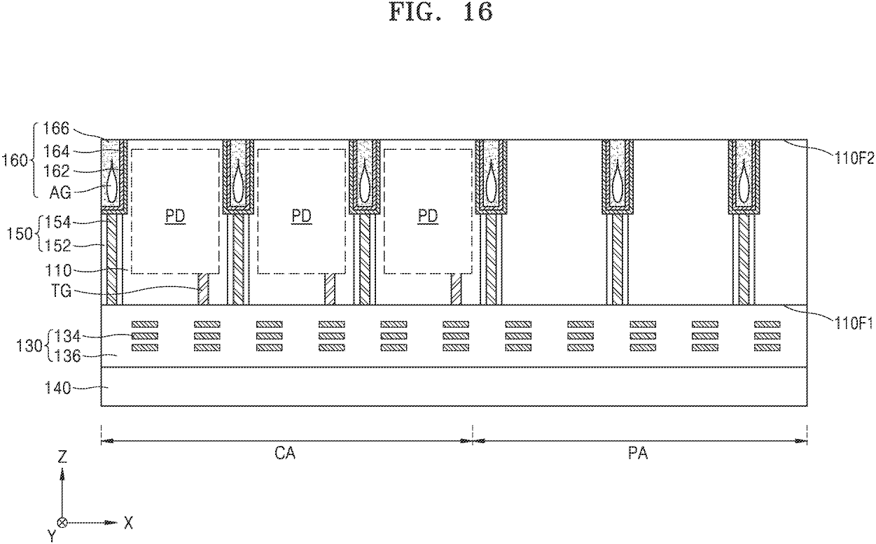

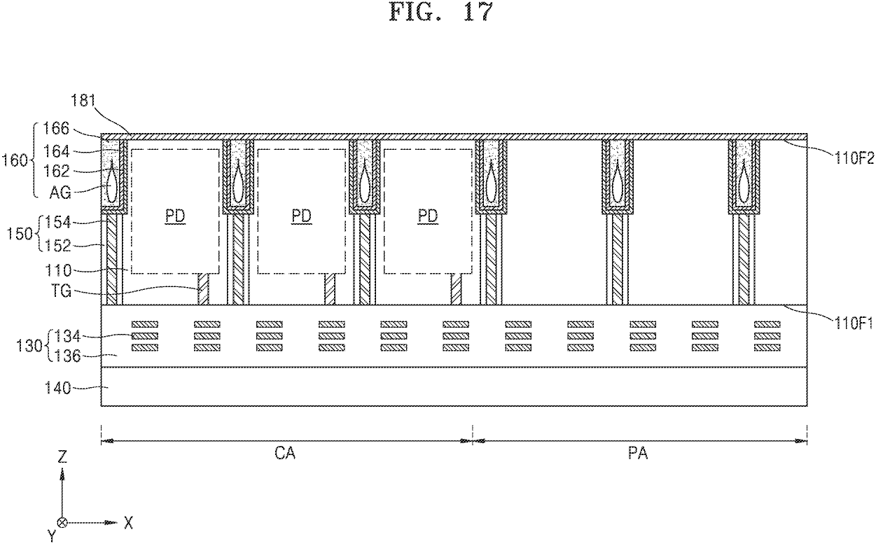

Referring to FIG. 13, a preliminary insulating liner 162L may be conformally formed on the inner walls of the second surface 110F2 and the second trench 160T of the substrate 110.

The preliminary insulating liner 162L may include silicon oxide or a high-k dielectric material layer with a higher dielectric constant than silicon oxide.

The preliminary insulating liner 162L may be conformally formed with substantially the same thickness along the inner space limited to the substrate 110 by the second trench 160T having a high aspect ratio.

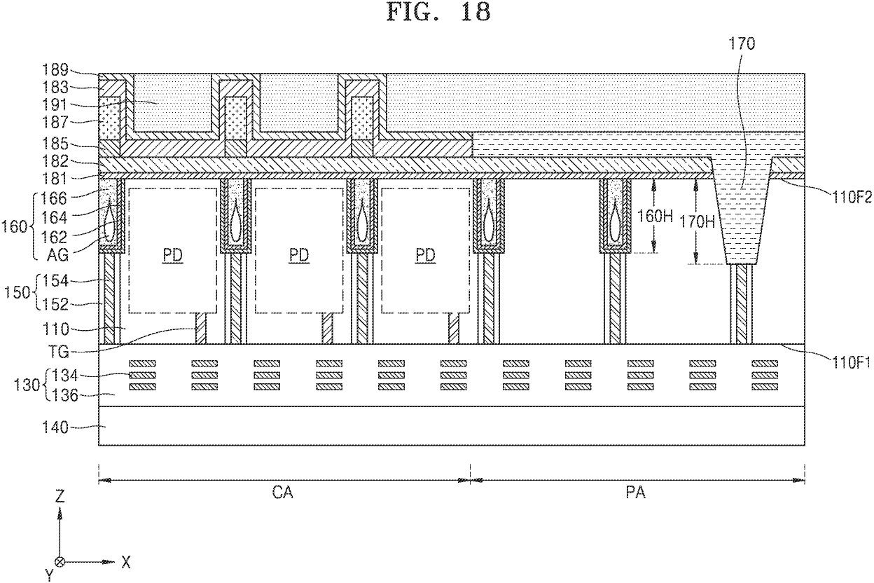

Referring to FIG. 14, a preliminary trap conductive film 164L may be conformally formed on the preliminary insulating liner 162L.

The preliminary trap conductive film 164L may include at least one of for example; doped polysilicon, titanium (Ti), tungsten (W), aluminum (Al), and indium tin oxide (ITO). Thus, the preliminary trap conductive film 164L made include one or more electrically conductive materials arranged to be electrically connected to a contact region 170, as described in some additional detail hereafter with reference to FIG. 18.

The preliminary trap conductive film 164L may be conformally formed on the preliminary insulating liner 162L with substantially the same thickness along the inner space limited to the substrate 110 by the second trench 160T having a high aspect ratio.

Referring to FIG. 15, a preliminary insulating filling layer 166L filling the second trench 160T and having an air gap AG therein may be formed.

The preliminary insulating filling layer 166L may include an oxide film formed by a process having relatively poor step coverage. For example, the preliminary insulating filling layer 166L may include at least one of PE-OX, TEOS, and PE-TEOS, but is not limited thereto. The preliminary insulating filling layer 166L may include silicon oxide, silicon nitride, or silicon oxynitride. In some embodiments, the preliminary insulating filling layer 166L may include a low-k dielectric material layer having a dielectric constant lower than that of silicon oxide.

The preliminary insulating filling layer 166L may include a material film formed by a process having relatively poor step coverage. The air gap AG may refer to a portion where the preliminary insulating filling layer 166L does not fill a space of the second trench 160T. That is, because the space of the second trench 160T has a large aspect ratio, a process with good step coverage should be used to entirely fill the second trench 160T. However, in order to intentionally form the air gap AG, the method of manufacture for an image sensor according to embodiments of the inventive concept may use a process having relatively poor step coverage during the formation of the preliminary insulating filling layer 166L.

Referring to FIG. 16, some portions of the preliminary insulating filling layer 166L (see FIG. 15), the preliminary trap conductive film 164L (see FIG. 15), and the preliminary insulating liner 162L (see FIG. 15) may be removed, such that the second surface 110F2 of the substrate 110 is exposed by a planarization process.

The second isolation region 160 may be formed in the second trench 160T by a planarization process, such as a CMP process or an etch-back process. The planarization process may be a node isolation process in which the second surface 110F2 of the substrate 110 is used as an etching stop layer to form the second isolation region 160 as each node.

Referring to FIG. 17, the first anti-reflection layer 181 may be formed on the second surface 110F2 of the substrate 110.

The first anti-reflection layer 181 may be disposed on all the photoelectric conversion devices PD and the second isolation region 160. Specifically, the lowermost surface of the first anti-reflection layer 181 may be in direct contact with the uppermost surface of the insulating liner 162, the uppermost surface of the trap conductive film 164, and the uppermost surface of the insulating filling layer 166 of the second isolation region 160. However, the lowermost surface of the first anti-reflection layer 181 may not be in contact with the air gap AG of the second isolation region 160.

Referring to FIG. 18, a second anti-reflection layer 182 may be formed on the first anti-reflection layer 181.

Next, the contact region 170 may be formed. The contact region 170 may be formed to be electrically connected to the first isolation region 150 in the vertical direction. Specifically, the contact region 170 may be disposed at a grid point in a grid shape formed by the second isolation region 160. That is, a part of the second isolation region 160 may be removed by etching, and the contact region 170 may be formed at a position where the second isolation region 160 is removed. The contact region 170 may include a metal material, such as tungsten. The contact region 170 may be formed to be in contact with a portion of the first isolation region 150 and the trap conductive film 164 of the second isolation region 160.

Next, a barrier metal layer 185 and a fence 187 may be formed on the second anti-reflection layer 182. In addition, a third anti-reflection layer 183 may be formed on the second anti-reflection layer 182 and the fence 187. In addition, a passivation layer 189 may be formed on the third anti-reflection layer 183. In addition, the color filters 191 may be formed on the passivation layer 189, and the color filters 191 may be isolated from each other by the fences 187.

Referring back to FIG. 4, the microlens 193 may be formed on the color filter 191 and the passivation layer 189. Next, the capping layer 195 may be formed on the microlens 193. In this way, the image sensor 100 according to the inventive concept may be completed.

Ultimately, the method of manufacture for image sensors according to embodiments of the inventive concept yields image sensors capable of providing a remarkably clear image signal by arranging the trap conductive film 164 capable of trapping surplus electrons in the second isolation region 160 corresponding to the BDTI.

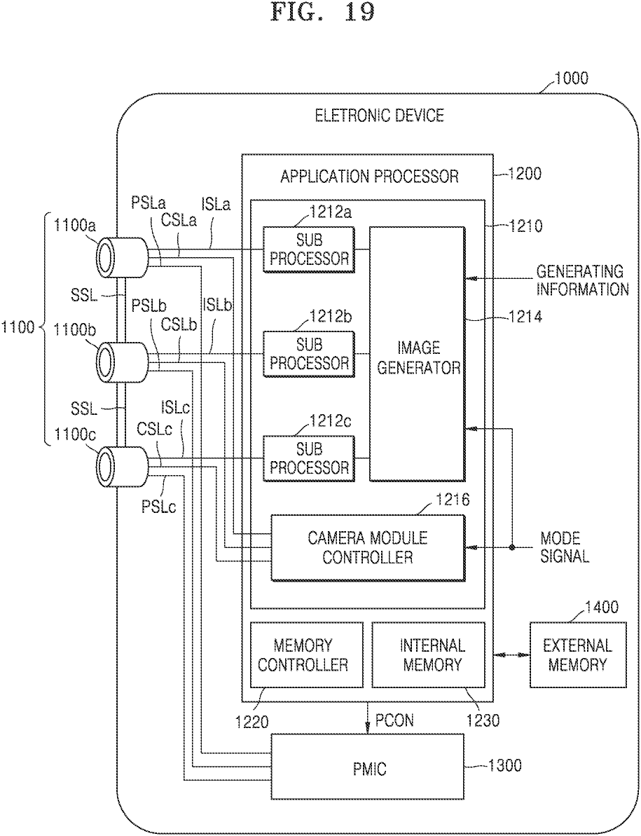

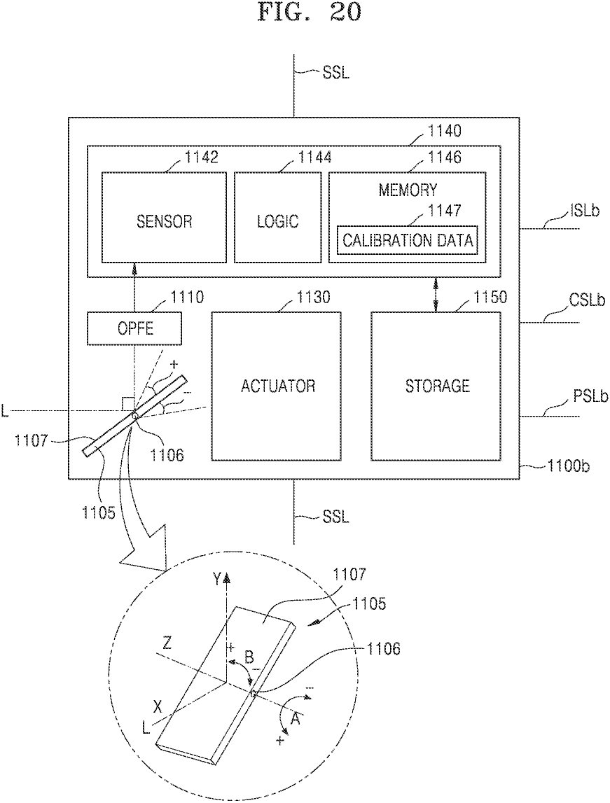

FIG. 19 is a block diagram of an electronic device including a multi-camera module, and FIG. 20 is a block diagram further illustrating the camera module of FIG. 19.

Referring to FIG. 19, an electronic device 1000 may include a camera module group 1100, an application processor 1200, a power management integrated circuit (PMIC) 1300, and a storage 1400.

The camera module group 1100 may include camera modules 1100a, 1100b, and 1100c. Although an embodiment where three camera modules 1100a, 1100b, and 1100c are arranged in the drawing is shown, the other embodiments are not limited thereto. In some embodiments, the camera module group 1100 may be implemented by including only two camera modules, or by modification to include n camera modules (here, n is a natural number of 4 or more).

Referring to FIG. 20, the camera module 1100b may include a prism 1105, an optical path folding element (OPFE) 1110, an actuator 1130, an image sensing device 1140, and a storage 1150.

Here, a detailed configuration of the camera module 1100b will be described in more detail, but the following description may be equally applied to the other camera modules 1100a and 1100c according to embodiments.

The prism 1105 may include a reflection surface 1107 of a light reflecting material to deform a path of incident light L.

In some embodiments, the prism 1105 may change the path of incident light L in the first horizontal direction to the second horizontal direction. In addition, the prism 1105 may rotate the reflection surface 1107 of the light reflecting material in the direction of “A” around the central axis 1106, or rotate the central axis 1106 in the direction of “B” to change the path of incident light L in the first horizontal direction to the second direction horizontal direction. In this case, the OPFE 1110 may also move in the vertical direction.

In some embodiments, as shown, the maximum rotation angle of the prism 1105 in the A direction may be 15° or less in the positive (+) A direction and greater than 15° in the negative (-) A direction, but the other embodiments are not limited thereto.

In some embodiments, the prism 1105 may move around 20° in a positive (+) or negative (-) B direction, or between 10° and 20°, or between 15° and 20°, where the moving angle may move at the same angle in a positive (+) or negative (-) B direction, or move to almost similar angles in a range around 1°.

In some embodiments, the prism 1105 may move the reflection surface 1107 of the light reflection material in the third direction (Z direction) parallel to the extending direction of the central axis 1106.

The OPFE 1110 may include, for example, optical lenses consisting of m groups (wherein ‘m’ is a natural number). The m lenses may move in the second horizontal direction to change the optical zoom ratio of the camera module 1100b. For example, when the basic optical zoom magnification of the camera module 1100b is Z, when m optical lenses included in the OPFE 1110 are moved, the optical zoom magnification of the camera module 1100b may be changed to an optical zoom magnification of 3Z, 5Z, or 5Z or more.

The actuator 1130 may move the OPFE 1110 or the optical lens to a specific position. For example, the actuator 1130 may adjust the position of the optical lens so that the image sensor 1142 is disposed at the focal length of the optical lens for accurate sensing.

The image sensing device 1140 may include an image sensor 1142, a control logic 1144, and a memory 1146. The image sensor 1142 may sense an image of an object to be sensed using light L provided through the optical lens. The control logic 1144 may control the overall operation of the camera module 1100b. For example, the control logic 1144 may control the operation of the camera module 1100b according to a control signal provided through a control signal line CSLb.

The memory 1146 may store information necessary for the operation of the camera module 1100b, such as calibration data 1147. The calibration data 1147 may include information necessary for the camera module 1100b to generate image data using light L provided from the outside. The calibration data 1147 may include, for example, information on the degree of rotation described above, information on the focal length, information on the optical axis, and the like. When the camera module 1100b is implemented in the form of a multi-state camera in which the focal length varies according to the position of the optical lens, The calibration data 1147 may include a focal length value for each position (or each state) of the optical lens and information related to auto focusing.

The storage 1150 may store image data sensed through the image sensor 1142. The storage 1150 may be arranged outside the image sensing device 1140, and may be implemented in a stacked form with a sensor chip constituting the image sensing device 1140. In some embodiments, the storage 1150 may be implemented as electrically erasable programmable read-only memory (EEPROM), but the embodiments are not limited thereto.

Referring to FIGS. 19 and 20, in some embodiments, each of the camera modules 1100a, 1100b, and 1100c may include an actuator 1130. Accordingly, each of the camera modules 1100a, 1100b, and 1100c may include the same or different calibration data 1147 according to the operation of the actuator 1130 included therein.

In some embodiments, one of the camera modules 1100a, 1100b, and 1100c, for example, the camera module 1100b may be a camera module in the form of a folded lens including the prism 1105 and the OPFE 1110 described above, and the remaining camera modules (e.g., 1100a and 1100c) may be camera modules in a vertical form, which do not include the prism 1105 and the OPFE 1110, but the embodiments are not limited thereto.

In some embodiments, one (e. g., 1100c) of the camera modules 1100a, 1100b, and 1100c may be, for example, a vertical depth camera that extracts depth information using an infrared ray (IR). In this case, the application processor 1200 may merge image data provided from the depth camera with image data provided from another camera module (e.g., 1100a or 1100b) to generate a three-dimensional depth image.

In some embodiments, at least two (e.g., 1100a and 1100b) of the camera modules 1100a, 1100b, and 1100c may have different fields of view. In this case, for example, optical lenses of at least two camera modules (e.g., 1100a and 1100b) among the camera modules 1100a, 1100b, and 1100c may be different from each other, but are not limited thereto.

In addition, in some embodiments, the respective fields of view for the camera modules 1100a, 1100b, and 1100c may be different from each other. In this case, the respective optical lenses included in the camera modules 1100a, 1100b, and 1100c may also be different from each other, but are not limited thereto.

In some embodiments, the camera modules 1100a, 1100b, and 1100c may be physically separated from each other and arranged, respectively. That is, the sensing region of one image sensor 1142 is not divided and may be used by the cameras modules 1100a, 1100b, and 1100c, but an independent image sensor 1142 may be arranged in each of the cameras modules 1100a, 1100b, and 1100c.

Referring to FIG. 19, the application processor 1200 may include an image processing device 1210, a memory controller 1220, and an internal memory 1230. The application processor 1200 may be implemented separately from the camera modules 1100a, 1100b, and 1100c. For example, the application processor 1200 and the camera modules 1100a, 1100b, and 1100c may be implemented separately from each other as separate semiconductor chips.

The image processing device 1210 may include sub-image processors 1212a, 1212b, and 1212c, an image generator 1214, and a camera module controller 1216.

The image processing device 1210 may include the number of sub-image processors 1212a, 1212b, and 1212c corresponding to the number of camera modules 1100a, 1100b, and 1100c.

Image data generated from each of the camera modules 1100a, 1100b, and 1100c may be provided to the corresponding sub-image processors 1212a, 1212b, and 1212c through image signal lines ISLa, ISLb, and ISLc separated from each other. For example, image data generated from the camera module 1100a may be provided to the sub-image processor 1212a through the image signal line ISLa, image data generated from the camera module 1100b may be provided to the sub-image processor 1212b through the image signal line ISLb, and Image data generated from the camera module 1100c may be provided to the sub-image processor 1212c through the image signal line ISLc. Such image data transmission may be performed using, for example, a camera serial interface (CSI) based on a mobile industry processor interface (MIPI), but embodiments are not limited thereto.

In some embodiments, one sub-image processor may be disposed to correspond to a number of camera modules. For example, as shown, the sub-image processor 1212a and the sub-image processor 1212c are not separated from each other but integrated and implemented into one sub-image processor, and image data provided from the camera module 1100a and the camera module 1100c may be selected through a selection element (e.g., a multiplexer) and then provided to the integrated sub-image processor.

Image data provided to each of the sub-image processors 1212a, 1212b, and 1212c may be provided to the image generator 1214. The image generator 1214 may generate an output image using image data provided from each of the sub-image processors 1212a, 1212b, and 1212c according to image generating information or a mode signal.

Specifically, the image generator 1214 may merge at least some pieces of image data generated from the camera modules 1100a, 1100b, and 1100c having different fields of view according to the image generating information or the mode signals to generate an output image. In addition, the image generator 1214 may select at least one piece of image data generated from the camera modules 1100a, 1100b, and 1100c having different fields of view according to the image generating information or the mode signals to generate an output image.

In some embodiments, the image generating information may include a zoom signal or zoom factor. In addition, in some embodiments, the mode signal may be, for example, a signal based on a mode selected from a user.

When the image generating information is a zoom signal (or a zoom factor), and each of the camera modules 1100a, 1100b, and 1100c has different fields of view, the image generator 1214 may perform different operations according to the type of the zoom signal. For example, when the zoom signal is a first signal, the image data output from the camera module 1100a and the image data output from the camera module 1100c are merged, and then an output image may be generated by using the image data output from the camera module 1100b that is not used in merging with the merged image data. When the zoom signal is a second signal different from the first signal, the image generator 1214 may generate an output image by selecting at least one of image data output from each of the camera modules 1100a, 1100b, and 1100c without performing such image data merging. However, the embodiments are not limited thereto, and the method of processing image data may be modified and implemented as necessary.

In some embodiments, the image generator 1214 may receive image data having different exposure times from at least one of the sub-image processors 1212a, 1212b, and 1212c and perform a high dynamic range (HDR) process on the image data, thereby generating merged image data with increased dynamic range.

The camera module controller 1216 may provide a control signal to each of the camera modules 1100a, 1100b, and 1100c. The control signals generated from the camera module controller 1216 may be provided to the corresponding camera modules 1100a, 1100b, and 1100c through the control signal lines CSLa, CSLb, and CSLc, which are separated from each other, respectively.

At least one of the camera modules 1100a, 1100b, and 1100c is designated as a master camera module (for example, 1100b), depending on the image generating information or the mode signal including the zoom signal, and the remaining camera modules (e.g. 1100a and 1100c) may be designated as slave cameras. Such information may be included in the control signal and provided to the corresponding camera modules 1100a, 1100b, and 1100c through the control signal lines CSLa, CSLb, and CSLc, which are separated from each other.

The camera module operating as a master and a slave may be changed according to the zoom factor or the operation mode signal. For example, when the field of view of the camera module 1100a is wider than the field of view of the camera module 1100b and the zoom factor indicates a low zoom magnification, the camera module 1100b may operate as a master and the camera module 1100a may operate as a slave. Conversely, when the zoom factor exhibits a high zoom magnification, the camera module 1100a may operate as a master and the camera module (1100b) can operate as a slave.

In some embodiments, the control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit a sync enable signal to the camera module 1100b. The camera module 1100b receiving the sink enable signal may generate a sync signal based on the provided sink enable signal, and may provide the generated sink signal to the camera modules 1100a and 1100c through the sink signal line SSL. The camera module 1100b and the camera modules 1100a and 1100c may transmit image data to the application processor 1200 in synchronization with the sink signal.

In some embodiments, the control signals provided from the camera module controller 1216 to the camera modules 1100a, 1100b, and 1100c may include mode information according to the mode signal. Based on the mode information, the camera modules 1100a, 1100b, and 1100c may operate in a first operation mode and a second operation mode with respect to a sensing speed.

In the first operation mode, the camera modules 1100a, 1100b, and 1100c may generate an image signal at a first speed (e.g., generate an image signal at a first frame rate) to encode the image signal at a second speed higher than the first speed (e. g., encode an image signal of a second frame rate higher than the first frame rate), and transmit the encoded image signal to the application processor 1200. In this case, the second speed may be 30 times or less of the first speed.

The application processor 1200 stores the received image signal, that is, the encoded image signal, in the internal memory 1230 or the storage 1400 outside the application processor 1200. Then, the application processor 1200 reads and decodes the encoded image signal from the memory 1230 or the storage 1400, and displays image data generated based on the decoded image signal. For example, a corresponding sub-processor among the sub-image processors 1212a, 1212b, and 1212c of the image processing device 1210 may perform decoding, and may also perform image processing on the decoded image signal.

In the second operation mode, the camera modules 1100a, 1100b, and 1100c may generate an image signal at a third speed lower than the first speed (e.g., generate an image signal at a third frame rate lower than the first frame rate), and transmit the image signal to the application processor 1200. The image signal provided to the application processor 1200 may be an unencoded signal. The application processor 1200 may perform image processing on the received image signal or store the image signal in the memory 1230 or the storage 1400.

The PMIC 1300 may supply power, for example, power voltage, to each of the camera modules 1100a, 1100b, and 1100c. For example, under the control of the application processor 1200, the PMIC 1300 may supply the first power to the camera module 1100a through the power signal line PSLa, supply the second power to the camera module 1100b through the power signal line PSLb, and supply the third power to the camera module 1100c through the power signal line PSLc.

The PMIC 1300 may generate power corresponding to each of the camera modules 1100a, 1100b, and 1100c in response to a power control signal PCON from the application processor 1200 and also adjust a power level. The power control signal PCON may include power adjustment signals for each operating mode of the camera modules 1100a, 1100b, and 1100c. For example, the operation mode may include a low power mode, and in this case, the power control signal PCON may include information on a camera module operating in the low power mode and a set power level. The power levels provided to each of the camera modules 1100a, 1100b, and 1100c may be the same or different from each other. In addition, the respective power levels may be dynamically changed.

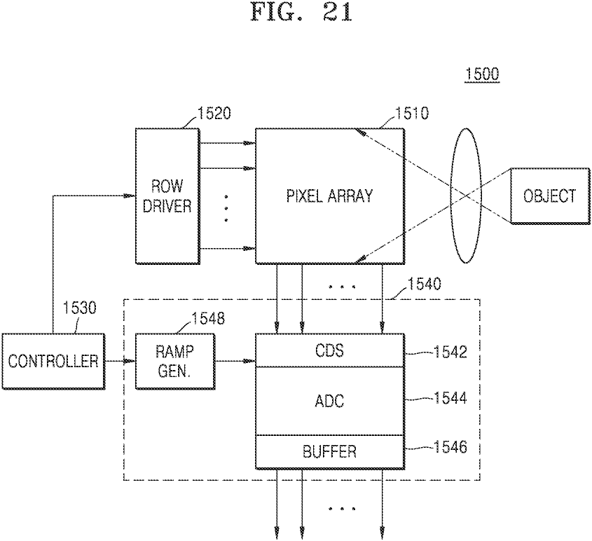

FIG. 21 is a block diagram illustrating an image sensor according to embodiments of the inventive concept.

Referring to FIG. 21, the image sensor 1500 may include a pixel array 1510, a controller 1530, a row driver 1520, and a pixel signal processor 1540.

The image sensor 1500 may include at least one of the image sensors 100 and 200 described above.

Thus, the pixel array 1510 may include unit pixels arranged in two dimensions, wherein each unit pixel includes a photoelectric conversion device. The photoelectric conversion device absorbs light to generate photo-charge, and an electrical signal (output voltage) according to the generated photo-charge may be provided to the pixel signal processor 1540 through a vertical signal line. The unit pixels included in the pixel array 1510 may provide an output voltage one at a time in row units, and thus the unit pixels belonging to one row of the pixel array 1510 may be simultaneously activated by a selection signal output by the row driver 1520. The unit pixels belonging to the selected row may provide an output voltage according to the absorbed light to an output line of a corresponding column.

The controller 1530 may control the row driver 1520 to allow the pixel array 1510 to absorb light to accumulate photo-charge, temporarily store the accumulated photo-charge, and output an electrical signal according to the stored photo-charge to the outside of the pixel array 1510. In addition, the controller 1530 may control the pixel signal processing unit 1540 to measure an output voltage provided by the pixel array 1510.

The pixel signal processing unit 1540 may include a correlation double sampler (CDS) 1542, an analog-to-digital converter (ADC) 1544, and a buffer 1546. The correlation double sampler 1542 may sample and hold an output voltage provided by the pixel array 1510.

The correlation double sampler 1542 may double-sample a specific noise level and a level in accordance with the generated output power voltage, and output a level corresponding to the difference. In addition, the correlation double sampler 1542 may receive a ramp signal generated by a ramp generator 1548, compare the ramp signal with each other, and output a comparison result.

The analog-to-digital converter 1544 may convert an analog signal corresponding to a level received from the correlation double sampler 1542 into a digital signal. The buffer 1546 may latch a digital signal, and the latched signals may be sequentially output to the outside of the image sensor 1500 and transferred to an image processor (not shown).

While the inventive concept has been particularly shown and described with reference to embodiments thereof, it will be understood that various changes in form and details may be made therein without departing from the scope of the following claims a defined by the following claims.

What is claimed is:

1. An image sensor comprising:
a substrate having a first surface and an opposing second surface and including a photoelectric conversion region;
a first isolation region extending vertically into the substrate from the first surface of the substrate;
a second isolation region extending vertically into the substrate from the second surface of the substrate and corresponding to the first isolation region;
a photoelectric conversion device disposed at a central portion of the photoelectric conversion region of the substrate; and
a contact region extending vertically from the second surface of the substrate to electrically connect the first isolation region at a peripheral portion of the photoelectric conversion region,
wherein the second isolation region includes:
a trench;
an insulating liner conformally formed on an inner wall of the trench;
a trap conductive film conformally formed on an inner wall of the insulating liner; and
an insulating filling layer filling a residual portion of the trench and including an air gap.

2. The image sensor of claim 1, wherein the trap conductive film of the second isolation region is electrically connected to the contact region.

3. The image sensor of claim 1, further comprising:
an anti-reflection layer covering the second surface of the substrate and the second isolation region,
wherein a lowermost surface of the anti-reflection layer directly contacts an uppermost surface of the insulating liner, an uppermost surface of the trap conductive film, and an uppermost surface of the insulating filling layer, and
the lowermost surface of the anti-reflection layer does not contact the air gap.

4. The image sensor of claim 1, wherein the trap conductive film includes at least one of doped polysilicon, titanium (Ti), tungsten (W), aluminum (Al), and indium tin oxide (ITO), and
the insulating filling layer includes an oxide layer formed by a process having poor step coverage.

5. The image sensor of claim 1, wherein the first isolation region and the second isolation region are respectively arranged in a lattice pattern, and
the contact region is disposed at a lattice point of the second isolation region in the peripheral portion.

6. The image sensor of claim 5, wherein, a length of the second isolation region vertically extending from the second surface of the substrate is less than a length of the contact region vertically extending from the second surface of the substrate.

7. The image sensor of claim 1, wherein the first isolation region and the second isolation region are in direct contact and penetrate the substrate.

8. The image sensor of claim 7, wherein the first isolation region includes a first trench, an insulating barrier conformally formed on an inner wall of the first trench, and a conductive filling film filling the first trench, and
the insulating liner directly contacts the insulating barrier and the conductive filling film in the first isolation region.

9. The image sensor of claim 8, wherein a first width of the first isolation region measured in a first horizontal direction is less than a second width of the second isolation region measured in the first horizontal direction.

10. The image sensor of claim 1, further comprising:
a color filter and a microlens disposed on an upper portion of the second surface of the substrate.

11. An image sensor comprising:
a substrate having a first surface and an opposing second surface, and including a photoelectric conversion region;
a first isolation region vertically extending into the substrate from the first surface of the substrate;
a second isolation region vertically extending into the substrate from the second surface of the substrate and corresponding to the first isolation region;
a photoelectric conversion device disposed at a central portion of the photoelectric conversion region; and
a contact region vertically extending into the substrate from the second surface of the substrate to electrically connect the first isolation region at a peripheral portion of the photoelectric conversion region,
wherein the second isolation region includes:
a trench;
an insulating liner conformally formed on an inner wall of the trench;
a trap conductive film conformally formed on an inner wall of the insulating liner and electrically connected to the contact region; and
an insulating filling layer entirely filling a residual portion of the trench.

12. The image sensor of claim 11, further comprising:
an anti-reflection layer covering the second surface of the substrate and the second isolation region,
wherein a lowermost surface of the anti-reflection layer is in direct contact with an uppermost surface of the insulating liner, an uppermost surface of the trap conductive film, and an uppermost surface of the insulating filling layer.

13. The image sensor of claim 11, wherein the trap conductive film includes at least one of doped polysilicon, titanium (Ti), tungsten (W), aluminum (Al), and indium tin oxide (ITO), and
the insulating filling layer includes an oxide layer formed by a process having good step coverage.

14. The image sensor of claim 13, wherein a first dielectric constant of the insulating liner is greater than a second dielectric constant of the insulating filling layer.

15. The image sensor of claim 11, a length of the second isolation region in a vertical direction from the second surface of the substrate is less than a length of the contact region in the vertical direction from the second surface of the substrate.

16. An image sensor comprising:
a substrate having a front surface and an opposing rear surface, and including a photoelectric conversion region;
a first isolation region arranged in a lattice pattern and vertically extending into the substrate from the front surface of the substrate, wherein the first isolation region includes; a first trench, an insulating barrier formed on an inner wall of the first trench, and a conductive filling film filling a residual portion of the first trench;
a second isolation region arranged in a lattice pattern and vertically extending into the substrate from the rear surface to contact the first isolation region, wherein the second isolation region includes; a second trench, an insulating liner conformally formed on an inner wall of the second trench, a trap conductive film conformally formed on an inner wall of the insulating liner, and an insulating filling layer filling a residual portion of the second trench and including an air gap; and
a contact region vertically extending from the rear surface to electrically connect the conductive filling film of the first isolation region and the trap conductive layer of the second isolation region,
wherein the photoelectric conversion region includes:
a photoelectric conversion device disposed in an inner portion of the substrate;
a color filter disposed on the rear surface of the substrate; and
a microlens disposed on the color filter.

17. The image sensor of claim 16, further comprising:
an anti-reflection layer covering the rear surface of the substrate and the second isolation region,
wherein a lowermost surface of the anti-reflection layer direct contacts an uppermost surface of the insulating liner, an uppermost surface of the trap conductive film, and an uppermost surface of the insulating filling layer, and
the lowermost surface of the anti-reflection layer does not contact the air gap.

18. The image sensor of claim 16, wherein the insulating liner of the second isolation region includes a high-k dielectric material formed by a process having good step coverage,
the trap conductive film of the second isolation region includes at least one of doped polysilicon, titanium (Ti), tungsten (W), aluminum (Al), and indium tin oxide (ITO), and
the insulating filling layer of the second isolation region includes a low-k dielectric material formed by a process having poor step coverage.

19. The image sensor of claim 16, wherein the insulating liner of the second isolation region direct contacts the insulating barrier and the conductive filling film of the first isolation region,
the contact region direct contacts the insulating barrier and the conductive filling film of the first isolation region, and
a length of the second isolation region in a vertical direction from the rear surface is less than a length of the contact region in the vertical direction from the rear surface.

20. The image sensor of claim 16, wherein each of the first trench and the second trench is a deep trench isolation.
